(19) United States
(12) Patent Application Publication
(10) Pub. No.: US 2025/0107346 A1
(43) Pub. Date: Mar. 27, 2025

(54) DISPLAY DEVICE

(71) Applicant: Samsung Display Co., Ltd., Yongin-si (KR)

(72) Inventor: GUANGHAI JIN, Yongin-si (KR)

(21) Appl. No.: 18/798,549

(22) Filed: Aug. 8, 2024

(30) Foreign Application Priority Data
Sep. 22, 2023 (KR) 10-2023-0127354
Aug. 5, 2024 (KR) 10-2024-0103621

(51) Int. Cl. H10K 59/122; H10K 39/34

(52) U.S. Cl. CPC H10K 59/122; H10K 39/34

(57) ABSTRACT

Provided is a display device comprising a base layer comprising a display region and a non-display region around the display region, unit elements on the display region, and comprising light-emitting elements and optical sensing elements, and a pixel-defining layer in which unit openings comprising light-emitting openings and sensing openings are defined. The light-emitting elements in the one of the unit elements comprise first, second, (3-1)-th, and (3-2)-th light-emitting elements for supplying light having colors different from each other, and a number of the optical sensing elements in the one of the unit elements may be equal to or more than a total number of the (3-1)-th light-emitting element and the (3-2)-th light-emitting element.

### CROSS-REFERENCE TO RELATED APPLICATIONS

The present application claims priority to, and the benefit of, Korean Patent Application No. 10-2023-0127354, filed on Sep. 22, 2023, and Korean Patent Application No. 10-2024-0103621, filed on Aug. 5, 2024 in the Korean Intellectual Property Office, the entire disclosure of which is incorporated herein by reference.

### BACKGROUND

### 1. Field

The present disclosure herein relates to a display device including an optical sensing element.

### 2. Description of the Related Art

An electronic apparatus for supplying an image to a user, such as a smartphone, a digital camera, a notebook computer, a navigation system, and a smart television, includes a display device for displaying the image. The display device may include a display panel for generating the image, an input unit, such as an input sensor, a camera for capturing an external image, and various sensors.

The input sensor may be located on the display panel, and may detect a user's touch. The sensors may include a fingerprint sensor, a proximity sensor, an illuminance sensor, etc. Among the sensors, the fingerprint sensor may detect a user's fingerprint on the display panel.

### SUMMARY

The present disclosure provides a display device of which an optical sensor has improved sensitivity.

One or more embodiments of the present disclosure provides a display device including a base layer including a display region, and a non-display region around the display region in plan view, unit elements at the display region, and including light-emitting elements and optical sensing elements, and a pixel-defining layer defining unit openings including light-emitting openings for supplying light generated by the light-emitting elements, and sensing openings respectively overlapping the optical sensing elements, wherein the light-emitting elements include a first light-emitting element for supplying light of a first color, a second light-emitting element for supplying light of a second color that is different from the first color, and spaced apart from the first light-emitting element along a first direction, and a (3-1)-th light-emitting element and a (3-2)-th light-emitting element for supplying light of a third color that is different from the first color and from the second color, and spaced apart along a second direction crossing the first direction, and a number of the optical sensing elements in one of the unit elements is equal to or greater than 2.

The optical sensing elements in the one of the unit elements may include a first optical sensing element between the (3-1)-th light-emitting element and the (3-2)-th light-emitting element, and a second optical sensing element spaced apart from the first optical sensing element along the first direction with the second light-emitting element therebetween, wherein the light-emitting openings in one of the unit openings include a first light-emitting opening overlapping the first light-emitting element, a second light-emitting opening overlapping the second light-emitting element, a (3-1)-th light-emitting opening overlapping the (3-1)-th light-emitting element, and a (3-2)-th light-emitting opening overlapping the (3-2)-th light-emitting element, and wherein the sensing openings in the one of the unit openings include a first sensing opening overlapping the first optical sensing element, and a second sensing opening overlapping the second optical sensing element.

First sensing openings and second sensing openings respectively in ones of the unit openings, which are arranged along the first direction, may be aligned along the first direction.

First sensing openings and second sensing openings respectively in ones of the unit openings, which arranged along the second direction, may be alternately arranged to have a zigzag form along the second direction.

The first sensing opening and the second sensing opening may respectively have a shape of a rectangle including short sides extending in the first direction, and long sides extending in the second direction.

The first light-emitting opening and the second light-emitting opening may have a hexagonal shape corresponding to an imaginary rectangle extending in a diagonal direction crossing the first direction and the second direction, and from which a first portion facing one of the long sides of the first sensing opening in the first direction, and a second portion that is point-symmetrical with the first portion, are removed.

The (3-1)-th light-emitting opening and the (3-2)-th light-emitting opening may have a hexagonal shape corresponding to an imaginary rectangle from which a third portion facing short sides of the first sensing opening in the second direction, and a fourth portion that is point-symmetrical with the third portion, are removed.

A length of a side of the first light-emitting opening facing the first sensing opening in the first direction may be greater than a length of a side of the (3-1)-th light-emitting opening facing the first sensing opening in the second direction.

The first light-emitting opening may include a first side facing the first sensing opening in the first direction, and a second side facing the (3-1)-th light-emitting opening in a first diagonal direction crossing the first direction and the second direction, wherein the second light-emitting opening includes a third side facing the first sensing opening in the first direction, and a fourth side facing the (3-1)-th light-emitting opening in a second diagonal direction crossing the first diagonal direction, and wherein a ratio of the second side to the first side is greater than a ratio of the fourth side to the third side.

A length of a first side of the (3-1)-th light-emitting opening facing the first light-emitting opening in a first diagonal direction, which crosses the first direction and the second direction, may be greater than a length of a second side of the (3-1)-th light-emitting opening facing the second light-emitting opening in a second diagonal direction, which crosses the first diagonal direction.

The (3-1)-th light-emitting opening and the (3-2)-th light-emitting opening may be line-symmetrical with respect to an imaginary line extending in the first direction.

The optical sensing elements in the one of the unit elements may include a first optical sensing element between the (3-1)-th light-emitting element and the (3-2)-th light-emitting element, a second optical sensing element spaced apart from the first optical sensing element along the first direction with the second light-emitting element therebetween, a third optical sensing element spaced apart from the first light-emitting element in a first diagonal direction crossing the first direction and the second direction, and a fourth optical sensing element spaced apart from the third optical sensing element along the second direction with the second light-emitting element therebetween, and spaced apart from the first optical sensing element in a second diagonal direction crossing the first diagonal direction, wherein the light-emitting openings in the one of the unit openings include a first light-emitting opening overlapping the first light-emitting element, a second light-emitting opening overlapping the second light-emitting element, a (3-1)-th light-emitting opening overlapping the (3-1)-th light-emitting element, and a (3-2)-th light-emitting opening overlapping the (3-2)-th light-emitting element, and wherein the sensing openings in the one of the unit openings include a first sensing opening overlapping the first optical sensing element, a second sensing opening overlapping the second optical sensing element, a third sensing opening overlapping the third optical sensing element, and a fourth sensing opening overlapping the fourth optical sensing element.

The first sensing openings and the second sensing openings respectively in the unit openings arranged along the first direction may be aligned along the first direction.

The third sensing openings and the fourth sensing openings respectively in the unit openings arranged along the second direction are aligned along the second direction.

The first sensing openings and the second sensing openings may have a shape of a rectangle including first sides extending in the first direction, and second sides extending in the second direction, and having a greater length than the first sides, wherein the third sensing openings and the fourth sensing openings have a shape of a rectangle including third sides extending in the first direction, and fourth sides extending in the second direction, and having a smaller length than the third sides.

The first light-emitting opening and the second light-emitting opening may have an octagonal shape corresponding to an imaginary square from which corners are removed.

The (3-1)-th light-emitting opening may have a hexagonal shape extending in a first diagonal direction crossing the first direction and the second direction, wherein the (3-2)-th light-emitting opening has a hexagonal shape extending in a second diagonal direction crossing the first diagonal direction.

The sensing openings may include short sides extending in the first direction, and long sides extending in the second direction, wherein a distance from one of the long sides of one of the sensing openings to a facing one of the light-emitting openings along the first direction is substantially equal to a distance from one of the short sides of the one of sensing openings to a facing another of the light-emitting openings along the second direction.

The first color may be blue, the second color may be red, and the third color may be green.

The light-emitting elements may include a first electrode at least partially exposed by the light-emitting openings, a second electrode, and a light-emitting layer between the first electrode and the second electrode, wherein the optical sensing elements include a first sensing electrode at least partially exposed by the sensing opening, a second sensing electrode, and a photoelectric conversion layer between the first sensing electrode and the second sensing electrode, and wherein the second electrode and the second sensing electrode are a common layer having an integrated shape.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a perspective view of a display device according to one or more embodiments of the present disclosure;

FIG. 2 is a diagram illustrating a cross-section of a display device illustrated in FIG. 1;

FIG. 3 is a diagram illustrating a cross-section of a display panel illustrated in FIG. 2;

FIG. 4 is a block diagram of a display device according to one or more embodiments of the present disclosure;

FIG. 5 is a diagram illustrating an equivalent circuit of any one pixel of pixels illustrated in FIG. 4 and an optical sensor adjacent to the pixel;

FIG. 6 is a diagram illustrating cross-sections of a light-emitting element, a first transistor, a fourth transistor, and a sixth transistor of a pixel illustrated in FIG. 5;

FIG. 7 is a diagram illustrating cross-sections of an optical sensing element, a first sensing transistor, and a second sensing transistor of an optical sensor illustrated in FIG. 5;

FIG. 8A is a diagram illustrating an arrangement state on a plane of light-emitting openings and sensing openings according to one or more embodiments of the present disclosure;

FIG. 8B is an enlarged diagram of one unit region illustrated in FIG. 8A;

FIG. 8C is an u enlarged diagram of one nit region illustrated in FIG. 8A;

FIG. 8D is a cross-sectional view taken along I-I′ of FIG. 8C;

FIG. 8E is a cross-sectional view taken along I-I′ of FIG. 8C

FIG. 9A is a diagram illustrating an arrangement state on a plane of light-emitting openings and sensing openings according to one or more embodiments of the present disclosure;

FIG. 9B is an enlarged diagram of one unit region illustrated in FIG. 9A; and

FIG. 10 illustrates a process of securing fingerprint information, which is biometric information, by optical sensors according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments will be described with reference to the drawings.

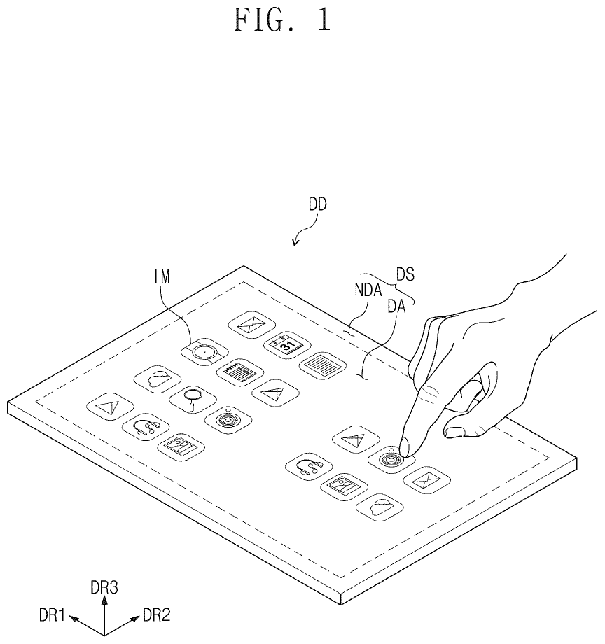

FIG. 1 is a perspective view of a display device according to one or more embodiments of the present disclosure.

Referring to FIG. 1, a display device DD according to one or more embodiments of the present disclosure may have a rectangular shape having long sides extending in a first direction DR1, and short sides extending in a second direction DR2 crossing the first direction DR1. However, the present disclosure is not limited thereto, and the display device DD may have various shapes, such as a circle, or a polygon. Hereinafter, a direction substantially perpendicularly crossing a plane defined by the first direction DR1 and the second direction DR2 is defined as a third direction DR3. In the present specification, “when seen on a plane” or “in plan view” is defined as a state of being seen in the third direction DR3.

An upper surface of the display device DD may be defined as a display surface DS, and may have a plane defined by the first direction DR1 and the second direction DR2. Images IM generated by the display device DD may be supplied to a user through the display surface DS.

The display surface DS may include a display region DA, and a non-display region NDA around the display region DA. The display region DA displays an image, and the non-display region NDA does not display the image. The non-display region NDA may surround the display region DA, but the present disclosure is not limited thereto, and the non-display region NDA may not be located on a side of the display region DA.

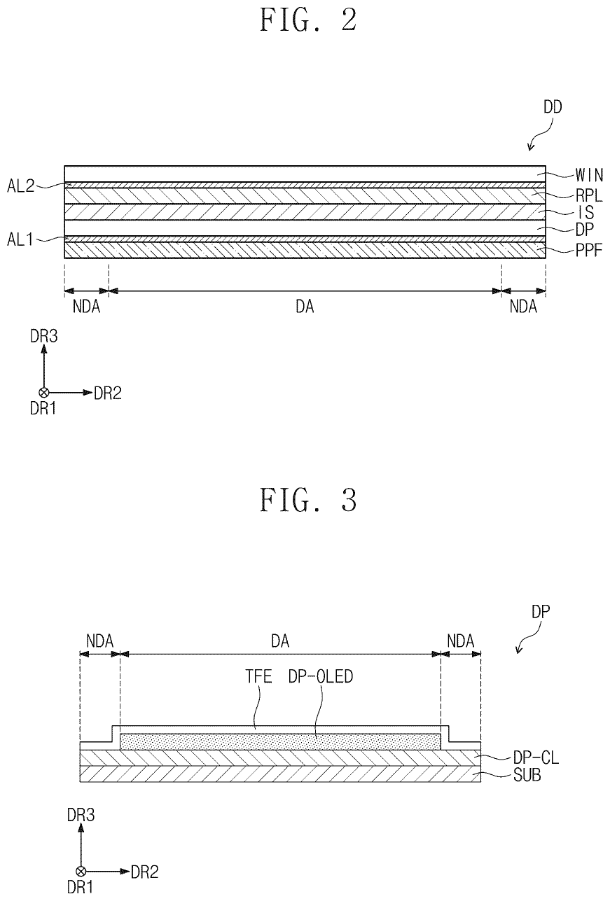

FIG. 2 illustrates a cross-section of the display device illustrated in FIG. 1.

Referring to FIG. 2, the display device DD may include a display panel DP, an input sensor IS, an anti-reflective layer RPL, a window WIN, a panel-protecting film PPF, and first and second adhesive layers AL1 and AL2. In one or more embodiments of the present disclosure, the input sensor IS may be omitted.

The display panel DP according to one or more embodiments of the present disclosure may be a light-emitting display panel, but is not limited thereto. For example, the display panel DP may be an organic light-emitting display panel, or an inorganic light-emitting display panel. A light-emitting layer of the organic light-emitting display panel may include an organic light-emitting material. A light-emitting layer of the inorganic light-emitting display panel may include a quantum dot, a quantum rod, etc. Hereinafter, the display panel DP will be described as the organic light-emitting display panel.

The input sensor IS may be located on the display panel DP (as used herein, “on” or “located on” may mean “above”). In one or more embodiments, the input sensor IS may include a plurality of sensors for sensing an external input in a capacitive manner. When the display device DD is manufactured, the input sensor IS may be directly formed on the display panel DP, but the present disclosure is not limited thereto. The input sensor IS may be separately manufactured with the display panel DP, and then may be attached to the display panel DP by an adhesive layer.

The anti-reflective layer RPL may be located on the input sensor IS. When the display device DD is manufactured, the anti-reflective layer RPL may be directly formed on the input sensor IS. The anti-reflective layer RPL may include a color filter, and may further include a black matrix.

However, the present disclosure is not limited thereto, and the anti-reflective layer RPL may be separately manufactured, and then may be attached to the input sensor IS by an adhesive layer. The anti-reflective layer RPL may include an optical film, such as a polarizing film. The anti-reflective layer RPL may reduce reflectance of external light incident from the top of the display device DD toward the display panel DP. The anti-reflective layer RPL may reduce or prevent external light viewed by a user.

The window WIN may be located on the anti-reflective layer RPL. The window WIN may protect the display panel DP, the input sensor IS, and the anti-reflective layer RPL from an external scratch and an impact.

The panel-protecting film PPF may be located under the display panel DP. The panel-protecting film PPF may protect a lower surface of the display panel DP. The panel-protecting film PPF may include a flexible plastic material, such as polyethylene terephthalate (PET).

FIG. 3 is a diagram illustrating a cross-section of the display panel illustrated in FIG. 2.

Referring to FIG. 3, a display panel DP may include a base layer SUB, a circuit element layer DP-CL located on the base layer SUB, a display element layer DP-OLED located on the circuit element layer DP-CL, and an encapsulation layer TFE located on the display element layer DP-OLED (as used herein, “on” may mean “above”).

Like the display device DD in FIG. 1, the base layer SUB may include a display region DA, and a non-display region NDA around the display region DA (e.g., in plan view). The base layer SUB may include a flexible plastic material, such as polyimide (PI), or glass.

The circuit element layer DP-CL may include a driver of a light-emitting element and a driver of an optical sensing element. The display element layer DP-OLED may include the light-emitting element and the optical sensing element. The encapsulation layer TFE may be located on the circuit element layer DP-CL to cover the display element layer DP-OLED. The encapsulation layer TFE may protect pixels from moisture, oxygen, and external foreign matters.

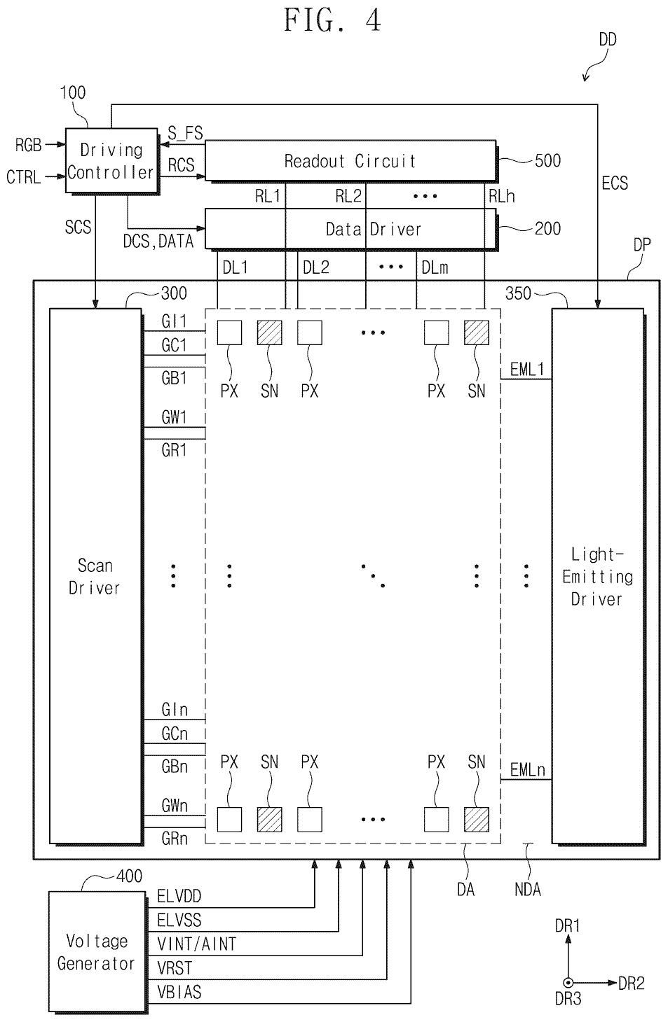

FIG. 4 is a block diagram of a display device according to one or more embodiments of the present disclosure.

Referring to FIG. 4, a display device DD includes a display panel DP, a driving controller 100, and a driver of the display device DD. In one or more embodiments of the present disclosure, the driver of the display device DD includes a data driver 200, a scan driver 300, a light-emitting driver 350, a voltage generator 400, and a readout circuit 500. In one or more embodiments of the present disclosure, the voltage generator 400 and the readout circuit 500 may be performed as one driving chip with the driving controller 100.

The display panel DP may include a plurality of pixels PX located in a display region DA, and a plurality of optical sensors SN located in the display region DA. In one or more embodiments of the present disclosure, the plurality of optical sensors SN may be respectively located between two adjacent pixels PX. However, a disposition relationship of the optical sensors SN and the pixels PX is not limited thereto.

The display panel DP may include initialization scan lines GI1 to GIn, compensation scan lines GC1 to GCn, bias scan lines GB1 to GBn, writing scan lines GW1 to GWn, light-emitting control lines EML1 to EMLn, reset scan lines GR1 to GRn, data lines DL1 to DLm, and readout lines RL1 to RLh. The initialization scan lines GI1 to GIn, the compensation scan lines GC1 to GCn, the bias scan lines GB1 to GBn, the writing scan lines GW1 to GWn, the light-emitting control lines EML1 to EMLn, and the reset scan lines GR1 to GRn extend in the second direction DR2. The data lines DL1 to DLm and the readout lines RL1 to RLh extend in the first direction DR1.

The plurality of pixels PX are electrically connected to the initialization scan lines GI1 to GIn, the compensation scan lines GC1 to GCn, the writing scan lines GW1 to GWn, the bias scan lines GB1 to GBn, the light-emitting control lines EML1 to EMLn, and the data lines DL1 to DLm. A number of signal lines connected to each of the pixels PX is not limited, and may differ in different embodiments.

The plurality of optical sensors SN are electrically connected to the writing scan lines GW1 to GWn, the reset scan lines GR1 to GRn, and the readout lines RL1 to RLh. A number of signal lines connected to each of the plurality of optical sensors SN is not limited, and may differ in different embodiments.

The driving controller 100 receives an image signal RGB and a control signal CTRL. The driving controller 100 generates an image data signal DATA for converting a data format of the image signal RGB to meet an interface specification with the data driver 200. The driving controller 100 outputs a first control signal DCS, a second control signal SCS, a third control signal ECS, and a fourth control signal RCS.

The data driver 200 receives the first control signal DCS and the image data signal DATA from the driving controller 100. The data driver 200 converts the image data signal DATA into data signals, and outputs the data signals to the plurality of data lines DL1 to DLm to be described later. The data signals are analog voltages corresponding to gradation values of the image data signal DATA.

The scan driver 300 receives the second control signal SCS from the driving controller 100. In response to the second control signal SCS, the scan driver 300 outputs initialization scan signals to the initialization scan lines GI1 to GIn, and compensation scan signals to the compensation scan lines GC1 to GCn. In addition, in response to the second control signal SCS, the scan driver 300 may output writing scan signals to the writing scan lines GW1 to GWn, and black scan signals to the bias scan lines GB1 to GBn. In addition, in response to the second control signal SCS, the scan driver 300 may output reset scan signals to the reset scan lines GR1 to GRn.

The light-emitting driver 350 receives the third control signal ECS from the driving controller 100. In response to the third control signal ECS, the light-emitting driver 350 may output light-emitting control signals to the light-emitting control lines EML1 to EMLn. Alternatively, the scan driver 300 may be connected to the light-emitting control lines EML1 to EMLn. In this case, the light-emitting driver 350 may be omitted, and the scan driver 300 may output the light-emitting control signals to the light-emitting control lines EML1 to EMLn (e.g., in response to the third control signal ECS).

The readout circuit 500 receives the fourth control signal RCS from the driving controller 100. In response to the fourth control signal RCS, the readout circuit 500 may receive sensing signals S_FS from the readout lines RL1 to RLh. The readout circuit 500 may process the sensing signals S_FS received from the readout lines RL1 to RLh, and may supply the processed sensing signals S_FS to the driving controller 100. The driving controller 100 may recognize biometric information on the basis of the sensing signals S_FS.

The voltage generator 400 generates voltages suitable for operating the display panel DP. The voltage generator 400 may generate a first driving voltage ELVDD, a second driving voltage ELVSS having a lower level than the first driving voltage ELVDD, a first initialization voltage VINT, a second initialization voltage AINT, a reset voltage VRST, and a bias voltage VBIAS.

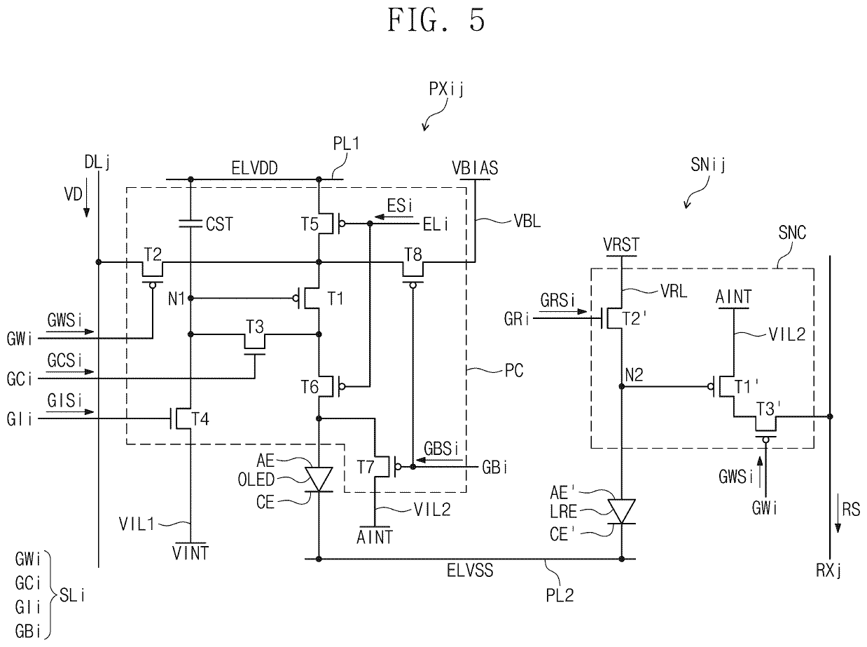

FIG. 5 is a diagram illustrating an equivalent circuit of any one pixel PXij of the pixels PX illustrated in FIG. 4, and an optical sensor SNij adjacent to the any one pixel PXij.

FIG. 5 illustrates i-th scan lines SLi, an i-th light-emitting line ELi, and a pixel PXij connected to a j-th data line DLj. In addition, FIG. 5 illustrates an i-th reset scan line GRi and the optical sensor SNij connected to a j-th readout line RXj, wherein i and j are natural numbers. The i-th scan lines SLi may include an i-th initialization scan line Gli, an i-th compensation scan line GCi, an i-th bias scan line GBi, and an i-th writing scan line GWi.

Referring to FIG. 5, the pixel PXij may include a pixel driver PC (or first driver) and a light-emitting element OLED electrically connected to the pixel driver PC. The light-emitting element OLED may be turned on or off by controlling the pixel driver PC.

The pixel driver PC may include a plurality of transistors T1, T2, T3, T4, T5, T6, T7, and T8 and a capacitor CST. The transistors T1, T2, T3, T4, T5, T6, T7, and T8 and the capacitor CST may control an amount of current flowing through the light-emitting element OLED. The light-emitting element OLED may generate light (e.g., light having a predetermined luminance) according to the amount of current supplied thereto.

The i-th writing scan line GWi may receive an i-th writing scan signal GWSi, and the i-th compensation scan line GCi may receive an i-th compensation scan signal GCSi. The i-th initialization scan line Gli may receive an i-th initialization scan signal GISi, and the i-th bias scan line GBi may receive an i-th bias scan signal GBSi. The i-th reset scan line GRi may receive an i-th reset scan signal GRSi. The i-th light-emitting line ELi may receive an i-th light-emitting signal ESi.

A first initialization line VIL1 may receive the first initialization voltage VINT, and a second initialization line VIL2 may receive the second initialization voltage AINT. A bias line VBL may receive the bias voltage VBIAS. A first power line PL1 may receive the first driving voltage ELVDD, and a second power line PL2 may receive the second driving voltage ELVSS. The light-emitting element OLED may be connected to the second power line PL2. A reset line VRL may receive the reset voltage VRST.

The transistors T1, T2, T3, T4, T5, T6, T7, and T8 may each include a source (or source terminal), a drain (or drain terminal), and a gate (or gate terminal). Hereinafter, for convenience's sake, any one of the source and the drain is defined as a first electrode, and the other of the source and the drain is defined as a second electrode. In addition, the gate is defined as a gate electrode or a control electrode.

Of the first to eighth transistors T1, T2, T3, T4, T5, T6, T7, and T8, the first, second, and fifth to eighth transistors T1, T2, T5, T6, T7, and T8 may be PMOS transistors. The third and fourth transistors T3 and T4 may be NMOS transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light-emitting control transistors. The eighth transistor T8 may be defined as a bias transistor.

The light-emitting element OLED may include an organic light-emitting diode. The light-emitting element OLED may include a first electrode, a second electrode, and a light-emitting layer located between the first electrode and the second electrode. For convenience of description, the first electrode is described as an anode AE, and the second electrode is described as a cathode CE. The anode AE may be electrically connected to the first power line PL1 through the sixth, first, and fifth transistors T6, T1, and T5. The cathode CE may be electrically connected to the second power line PL2. The first transistor T1 may be located between the fifth transistor T5 and the sixth transistor T6 to be connected to the fifth transistor T5 and to the sixth transistor T6. The first transistor T1 may be connected to the first power line PL1 through the fifth transistor T5, and may be connected to the anode AE through the sixth transistor T6. The first transistor T1 may include the first electrode connected to the first power line PL1 through the fifth transistor T5, may include the second electrode connected to the anode AE through the sixth transistor T6, and may include the gate electrode connected to a first node N1. The first electrode of the first transistor T1 may be connected to the fifth transistor T5, and the second electrode of the first transistor T1 may be connected to the sixth transistor T6. The first transistor T1 may control an amount of current flowing through the light-emitting element OLED according to a voltage of the first node N1 applied to the gate electrode of the first transistor T1.

The second transistor T2 may be located between the first transistor T1 and the j-th data line DLj to be connected to the first transistor T1 and to the j-th data line DLj. The second transistor T2 may include a first electrode connected to the j-th data line DLj, a second electrode connected to the first electrode of the first transistor T1, and a gate electrode connected to the i-th writing scan line GWi. The second transistor T2 may be turned on by the i-th writing scan signal GWSi applied through the i-th writing scan line GWi to electrically connect the j-th data line DLj and the first electrode of the first transistor T1. The second transistor T2 may perform a switching operation of supplying a data voltage VD from the j-th data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a gate electrode connected to the i-th compensation scan line GCi. The third transistor T3 may be turned on by the i-th compensation scan signal GCSi applied through the i-th compensation scan line GCi to electrically connect the second electrode of the first transistor T1 and the gate electrode of the first transistor T1. When the third transistor T3 is turned on, the first transistor T1 and the third transistor T3 may be connected in a diode form.

The fourth transistor T4 may be connected to the first node N1. The fourth transistor T4 may include a first electrode connected to the first node N1, a second electrode connected to the first initialization line VIL1, and a gate electrode connected to the i-th initialization scan line Gli. The fourth transistor T4 may be turned on by the i-th initialization scan signal GISi applied through the i-th initialization scan line Gli to supply the first initialization voltage VINT from the first initialization line VIL1 to the first node N1.

The fifth transistor T5 may include a first electrode connected to the first power line PL1, a second electrode connected to the first electrode of the first transistor T1, and a gate electrode connected to the i-th light-emitting line ELi. The sixth transistor T6 may include a first electrode connected to the second electrode of the first transistor T1, a second electrode connected to the anode AE, and a gate electrode connected to the i-th light-emitting line ELi. The fifth transistor T5 and the sixth transistor T6 may be turned on by the i-th light-emitting signal ESi applied through the i-th light-emitting line ELi. The first driving voltage ELVDD may be supplied to the light-emitting element OLED by the fifth transistor T5 and the sixth transistor T6 which are turned on, so that a driving current may flow through the light-emitting element OLED. Accordingly, the light-emitting element OLED may emit light.

The seventh transistor T7 may include a first electrode connected to the anode AE, a second electrode connected to the second initialization line VIL2, and a gate electrode connected to the i-th bias scan line GBi. The seventh transistor T7 may be turned on by the i-th bias scan signal GBSi applied through the i-th bias scan line GBi to supply the second initialization voltage AINT from the second initialization line VIL2 to the anode AE of the light-emitting element OLED.

In one or more embodiments of the present disclosure, the seventh transistor T7 may be omitted. In one or more embodiments of the present disclosure, the second initialization voltage AINT may have a level that is different from the first initialization voltage VINT. However, the present disclosure is not limited thereto, and the second initialization voltage AINT may have the same level as the first initialization voltage VINT.

The seventh transistor T7 may improve black-expressing ability of the pixel PXij. When the seventh transistor T7 is turned on, a parasitic capacitor of the light-emitting element OLED may be discharged. Accordingly, when black luminance is performed, the light-emitting element OLED may not emit light due to a leakage current of the first transistor T1, thereby improving the black-expressing ability.

The capacitor CST may include a first electrode connected to the first power line PL1 and a second electrode connected to the first node N1. When the fifth transistor T5 and the sixth transistor T6 are turned on, an amount of current flowing through the first transistor T1 may be determined by a voltage stored in the capacitor CST.

The eighth transistor T8 may include a first electrode connected to the bias line VBL, a second electrode connected to the first electrode of the first transistor T1, and a gate electrode connected to the i-th bias scan line GBi. In one or more embodiments of the present disclosure, the eighth transistor T8 may be omitted. The eighth transistor T8 may be turned on by the i-th bias scan signal GBSi, and may supply the bias voltage VBIAS to the first electrode of the first transistor T1. Because the bias voltage VBIAS is applied to the first transistor T1, a hysteresis curve of the first transistor T1 may be suppressed from moving.

The optical sensor SNij may include a sensor driver SNC (or second driver) and an optical sensing element LRE electrically connected to the sensor driver SNC. The sensor driver SNC may detect an operation of the optical sensing element LRE.

The sensor driver SNC may include a first sensing transistor T1′, a second sensing transistor T2′, and a third sensing transistor T3′. The first and third sensing transistors T1′ and T3′ may be PMOS transistors, and the second sensing transistor T2′ may be an NMOS transistor.

The optical sensing element LRE may be defined as a photo diode. The optical sensing element LRE may convert optical energy incident from the outside to electric energy. The optical sensing element LRE may include a first electrode, a second electrode, and a photoelectric conversion layer located between the first electrode and the second electrode.

For convenience of description, the first electrode is described as an anode AE′, and the second electrode is described as a cathode CE′. The anode AE′ may be connected to a second node N2, and the cathode CE′ may be connected to the second power line PL2. Meanwhile, to respectively distinguish the anode AE and the cathode CE of the light-emitting element OLED from the anode AE′ and the cathode CE′ of the optical sensing element LRE, the anode AE and the cathode CE of the light-emitting element OLED may be respectively defined as a first electrode and a second electrode, and the anode AE′ and the cathode CE′ of the optical sensing element LRE may be respectively defined as a (1-1)-th electrode and a (2-1)-th electrode.

The first sensing transistor T1′ may be connected to the optical sensing element LRE, the second sensing transistor T2′, and the third sensing transistor T3′. The first sensing transistor T1′ may include a first electrode receiving the second initialization voltage AINT, a gate electrode connected to the second node N2, and a second electrode connected to the third sensing transistor T3′. The first electrode of the first sensing transistor T1′ may be connected to the second initialization line VIL2 so as to receive the second initialization voltage AINT.

The second sensing transistor T2′ may include a first electrode connected to the second node N2, a gate electrode connected to the i-th reset scan line GRi, and a second electrode connected to the reset line VRL.

The third sensing transistor T3′ may include a first electrode connected to the second electrode of the first sensing transistor T1′, a gate electrode connected to the i-th writing scan line GWi, and a second electrode connected to the readout line RXj. The third sensing transistor T3′ may be turned on by the i-th writing scan signal GWSi received through the i-th writing scan line GWi.

The second sensing transistor T2′ may be turned on by the i-th reset scan signal GRSi received through the i-th reset scan line GRi. A turned-on second sensing transistor T2′ may supply the reset voltage VRST to the second node N2. The second node N2 may be reset by the reset voltage VRST.

The i-th writing scan signal GWSi may be applied to the gate electrode of the third sensing transistor T3′ to turn on the third sensing transistor T3′. The first sensing transistor T1′ may be connected to the readout line RXj by a turned-on third sensing transistor T3′.

The optical sensing element LRE may receive light to convert the light to an electric signal such that a voltage of the second node N2 may be changed. When the first sensing transistor T1′ is turned on, the second initialization voltage AINT supplied to the first sensing transistor T1′ may be controlled according to a voltage change of the second node N2 to be supplied to the readout line RXj through the third sensing transistor T3′. Accordingly, the signal detected by the optical sensing element LRE may be output as a sensing signal RS through the readout line RXj.

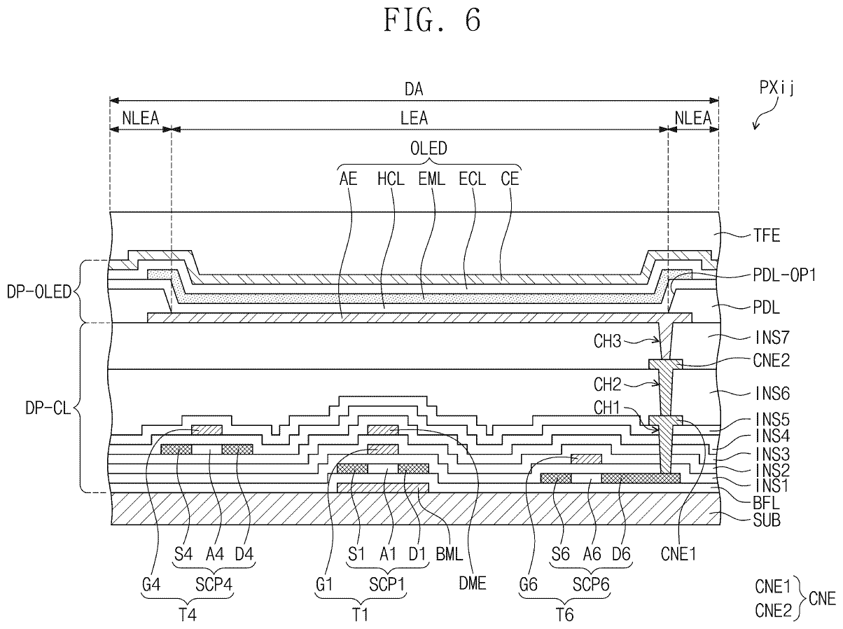

FIG. 6 is a diagram illustrating cross-sections of a light-emitting element OLED, a first sensing transistor T1, a fourth transistor T4, and a sixth transistor T6 of the pixel PXij illustrated in FIG. 5.

FIG. 6 illustrates the first, fourth, and sixth transistors T1, T4, and T6 of the pixel driver PC in FIG. 5. Referring to FIG. 6, a shielding layer BML may be located on a base layer SUB. The shielding layer BML may overlap the first transistor T1. The shielding layer BML may include metal, and a constant voltage may be applied to the shielding layer BML. When the constant voltage is applied to the shielding layer BML, a threshold voltage value of the first transistor T1 located on the shielding layer BML may be maintained without any change.

In addition, the shielding layer BML may block light incident from a lower portion of, or below, the shielding layer BML to the first transistor T1. For example, the shielding layer BML may include reflective metal. In one or more embodiments of the present disclosure, the shielding layer BML may be omitted.

A buffer layer BFL may be located on the base layer SUB, and may include an inorganic layer. The buffer layer BFL may cover the shielding layer BML. A semiconductor layer SCP1 (or semiconductor pattern region, hereinafter, described as a first semiconductor layer) of the first transistor T1, and a semiconductor layer SCP6 (or semiconductor pattern region, hereinafter, described as a sixth semiconductor layer) of the sixth transistor T6 may be located on the buffer layer BFL. Hereinafter, the first and sixth semiconductor layers SCP1 and SCP6 may include polysilicon. However, the present disclosure is not limited thereto, and the first and sixth semiconductor layers SCP1 and SCP6 may include amorphous silicon.

The first and sixth semiconductor layers SCP1 and SCP6 may be formed through the same process, and a partial region of each of the first and sixth semiconductor layers SCP1 and SCP6 may be doped with an N-type dopant or a P-type dopant. The first and sixth semiconductor layers SCP1 and SCP6 may include a highly doped region and a lowly doped region. The highly doped region has a greater conductive property than the lowly doped region. The highly doped regions may substantially correspond to a source region and a drain region of the first and sixth transistors T1 and T6. The lowly doped region may substantially correspond to an active region (or channel region) of each of the first and sixth transistors T1 and T6.

The highly doped region of the first semiconductor layer SCP1 may include a first source region S1 and a first drain region D1. The lowly doped region of the first semiconductor layer SCP1 is defined as a first channel region A1, and is located between the first source region S1 and the first drain region D1. The sixth semiconductor layer SCP6 may include a sixth source region S6, a sixth channel region A6, and a sixth drain region D6.

The first semiconductor layer SCP1 and the sixth semiconductor layer SCP6 are spaced apart from each other on a cross-section in FIG. 6, but may have an integrated shape on a plane. In other words, the first semiconductor layer SCP1 and the sixth semiconductor layer SCP6 may be different portions or different regions of one semiconductor pattern.

A first insulating layer INS1 covering the first and sixth semiconductor layers SCP1 and SCP6 may be located on the buffer layer BFL. Gate electrodes of the first and sixth transistors T1 and T6 are located on the first insulating layer INS1. The gate electrodes of the first and sixth transistors T1 and T6 may be formed through the same process. Hereinafter, the gate electrode of the first transistor T1 is defined as a first gate electrode G1, and the gate electrode of the sixth transistor T6 is defined as a sixth gate electrode G6.

A second insulating layer INS2 may be located on the first insulating layer INS1 so as to cover the first and sixth gate electrodes G1 and G6. A dummy electrode DME may be located on the second insulating layer INS2. The dummy electrode DME may be located on the first gate electrode G1, and may overlap the first gate electrode G1 when viewed on a plane. The dummy electrode DME and the first gate electrode G1 may form the capacitor CST described above. In other words, the first gate electrode G1 corresponds to one electrode of the capacitor CST, and the dummy electrode DME corresponds to the other electrode of the capacitor CST.

A third insulating layer INS3 may be located on the second insulating layer INS2 so as to the dummy electrode DME. A semiconductor layer SCP4 (or semiconductor pattern region, hereinafter, described as a fourth semiconductor layer) of the fourth transistor T4 may be located on the third insulating layer INS3. The fourth semiconductor layer SCP4 may include oxide semiconductor including metal oxide. The oxide semiconductor may include crystalline or amorphous oxide semiconductor.

The fourth semiconductor layer SCP4 may include a plurality of regions divided according to whether or not the metal oxide is reduced. A region (hereinafter, a reduced region) in which the metal oxide is reduced has a greater conductive property than a region (hereinafter, a non-reduced region) in which the metal oxide is not reduced. The reduced regions may substantially correspond to a source region and a drain region of the fourth transistor T4. The non-reduced region may substantially correspond to an active region (or channel region) of the fourth transistor T4.

The reduced regions of the fourth semiconductor layer SCP4 may include a fourth source region S4 and a fourth drain region D4. A fourth channel region A4 may be located between the fourth source region S4 and the fourth drain region D4.

A fourth insulating layer INS4 may be located on the third insulating layer INS3 so as to cover the fourth semiconductor layer SCP4. A fourth gate electrode G4 of the fourth transistor T4 may be located on the fourth insulating layer INS4.

A fifth insulating layer INS5 may be located on the fourth insulating layer INS4 so as to cover the fourth gate electrode G4. The buffer layer BFL and the first to fifth insulating layers INS1, INS2, INS3, INS4, and INS5 may include inorganic layers.

A connection electrode CNE may be located between the sixth transistor T6 and the light-emitting element OLED. The connection electrode CNE may electrically connect the sixth transistor T6 and the light-emitting element OLED. The connection electrode CNE may include a first connection electrode CNE1, and a second connection electrode CNE2 located on the first connection electrode CNE1.

The first connection electrode CNE1 may be connected to the sixth drain region D6 through a first contact hole CH1 located on the fifth insulating layer INS5, and may be defined in the first to fifth insulating layers INS1, INS2, INS3, INS4, and INS5. A sixth insulating layer INS6 may be located on the fifth insulating layer INS5 so as to cover the first connection electrode CNE1. The second connection electrode CNE2 may be located on the sixth insulating layer INS6. The second connection electrode CNE2 may be connected to the first connection electrode CNE1 through a second contact hole CH2 defined in the sixth insulating layer INS6. A seventh insulating layer INS7 may be located on the sixth insulating layer INS6 so as to cover the second connection electrode CNE2. The sixth and seventh insulating layers INS6 and INS7 may include an inorganic layer or an organic layer.

The light-emitting element OLED is located on the seventh insulating layer INS7. The light-emitting element OLED may include a first electrode AE, a second electrode CE, a hole control layer HCL, an electron control layer ECL, and a light-emitting layer EML. The first electrode AE may be the anode AE illustrated in FIG. 5, and the second electrode CE may be the cathode CE illustrated in FIG. 5. The second electrode CE may be located on/above the first electrode AE. The hole control layer HCL and the electron control layer ECL may be located between the first electrode AE and the second electrode CE. The light-emitting layer EML may be located between the hole control layer HCL and the electron control layer ECL.

A display region DA may include a light-emitting region LEA corresponding to the light-emitting element OLED, and a non-light-emitting region NLEA adjacent to the light-emitting region LEA. The first electrode AE may be located on the seventh insulating layer INS7. The first electrode AE may be electrically connected to the second connection electrode CNE2 through a third contact hole CH3 defined in the seventh insulating layer INS7.

A pixel-defining layer PDL for exposing a portion (e.g., a predetermined portion) of the first electrode AE may be located on the first electrode AE and on the seventh insulating layer INS7. A light-emitting opening PDL-OP1 for exposing the portion of the first electrode AE may be defined in, or defined by, the pixel-defining layer PDL. The light-emitting region LEA corresponds to the light-emitting opening PDL-OP1.

The hole control layer HCL may be located on the first electrode AE and the pixel-defining layer PDL. The hole control layer HCL may be commonly located in the light-emitting region LEA and the non-light-emitting region NLEA. The hole control layer HCL may include a hole transport layer and a hole injection layer.

The light-emitting layer EML may be located on the hole control layer HCL. The light-emitting layer EML may be located in a region corresponding to the light-emitting opening PDL-OP1. The light-emitting layer EML may include an organic material and/or an inorganic material. The light-emitting layer EML may generate light of any one color among, for example, a red color, a green color, and a blue color.

The electron control layer ECL may be located on the light-emitting layer EML and the hole control layer HCL. The electron control layer ECL may be commonly located in the light-emitting region LEA and the non-light-emitting region NLEA. The electron control layer ECL may include an electron transport layer and an electron injection layer.

The second electrode CE may be located on the electron control layer ECL. The second electrode CE may be commonly located in the pixels PX. That is, the second electrode CE may be a common layer having an integrated shape, and may be commonly located on the light-emitting layers EML of the pixels PX.

Layers from the buffer layer BFL to the seventh insulating layer INS7 may be defined as a circuit element layer DP-CL. A layer in which the light-emitting element OLED is located may be defined as a display element layer DP-OLED.

The encapsulation layer TFE may be located on the light-emitting element OLED. The encapsulation layer TFE may include an inorganic layer, an organic layer, and an inorganic layer sequentially stacked. The inorganic layers may each include an inorganic material, and may protect the pixels from moisture/oxygen. The organic layer may include an organic material, and may protect the pixels PX from foreign matters, such as dust particles.

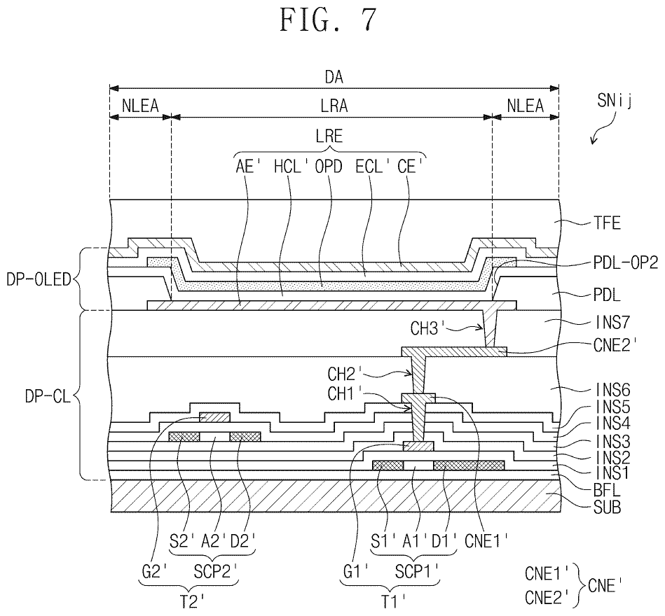

The encapsulation layer TFE may include the inorganic layers, and the organic layer located between the inorganic layers. The inorganic layers may reduce or prevent external moisture or oxygen from infiltrating the light-emitting layer EML and a photoelectric conversion layer OPD (see FIG. 7). For example, the inorganic layers may include silicon nitride, silicon oxide, or a combined compound thereof. The inorganic layers may be formed through deposition processes.

The organic layer may supply, or allow, a substantially flat surface. A curve formed on an upper surface of the inorganic layer located under the organic layer, or particles existing on the inorganic layer located under the organic layer, may be covered by the organic layer, thereby blocking a surface state of the upper surface of the inorganic surface located under the organic layer from affecting configurations formed on the organic layer. The organic layer may include an organic material, and may be formed through a solution process, such as spin coating, slit coating, or an inkjet process.

FIG. 7 is a diagram illustrating cross-sections of an optical sensing element LRE, a first sensing transistor T1′, and a second sensing transistor T2′ of the optical sensor SNij illustrated in FIG. 5. Hereinafter, detailed description for the same configurations as those described in FIG. 6 refers to the description in FIG. 6.

A semiconductor layer SCP1′ (hereinafter, a first sensing semiconductor layer) of a first sensing transistor T1′ may be formed through the same process as the first semiconductor layer SCP1 in FIG. 6. A semiconductor layer SCP2′ (hereinafter, a second sensing semiconductor layer) of a second sensing transistor T2′ may be formed through the same process as the fourth semiconductor layer SCP4 in FIG. 6. The first sensing semiconductor layer SCP1′ may include a first source region S1′, a first drain region D1′, and a first channel region A1′. The second sensing semiconductor layer SCP2′ may include a second source region S2′, a second drain region D2′, and a second region A2′.

A stack structure of the first sensing transistor T1′ may be substantially the same as a stack structure of the first transistor T1 illustrated in FIG. 6. A stack structure of the second sensing transistor T2′ may be substantially the same as a stack structure of the fourth transistor T4 illustrated in FIG. 6. In one or more embodiments, a stack structure of the third sensing transistor T3′ may be substantially the same as the stack structure of the first sensing transistor T1′.

A connection electrode CNE′ may include a first connection electrode CNE1′ (or first sensing connection electrode) and a second connection electrode CNE2′ (or second sensing connection electrode). The first connection electrode CNE1′ may be located on the same layer as the first connection electrode CNE1 illustrated in FIG. 6, and may be connected to a first gate electrode G1′ of the first sensing transistor T1′ through a first contact hole CH1′. Hereinafter, the first gate electrode G1′ is defined as a first sensing gate electrode G1′ so as to distinguish from the first gate electrode G1 described above.

The second connection electrode CNE2′ may be located on the same layer as the second connection electrode CNE2 illustrated in FIG. 6, and may be connected to the first connection electrode CNE1′ through a second contact hole CH2′ defined in the sixth insulating layer INS6.

Referring to FIG. 7, a display region DA may include a light-absorbing region LRA corresponding to the optical sensor SNij, and a non-light-emitting region NLEA adjacent to the light-absorbing region LRA. The non-light-emitting region NLEA may be the non-light-emitting region NLEA illustrated in FIG. 6.

The optical sensing element LRE may include a first electrode AE′, a second electrode CE′, a hole control layer HCL′, an electron control layer ECL′, and a photoelectric conversion layer OPD. The first electrode AE′ may be the anode AE′ illustrated in FIG. 5, and the second electrode CE′ may be the cathode CE′ illustrated in FIG. 5. A sensing opening PDL-OP2 for exposing a portion (e.g., predetermined portion) of the first electrode AE′ may be defined in the pixel-defining layer PDL. The light-absorbing region LRA corresponds to the sensing opening PDL-OP2. The first electrode AE′ may be connected to the second connection electrode CNE2′ through a third contact hole CH3′ defined in the seventh insulating layer INS7.

The first electrode AE′ is formed through the same process as the first electrode AE illustrated in FIG. 6. The second electrode CE′, the hole control layer HCL′, and the electron control layer ECL′ may respectively have an integrated shape with the second electrode CE, the hole control layer HCL, and the electron control layer ECL illustrated in FIG. 6. The second electrode CE′ in FIG. 7 and the second electrode CE in FIG. 6 may be different regions of a common layer. The common layer may be deposited so as to have an integrated shape through an open mask. The hole control layer HCL′ in FIG. 7 and the hole control layer HCL in FIG. 6 may be also different regions of a common hole control layer, and the electron control layer ECL′ in FIG. 7 and the electron control layer ECL in FIG. 6 may be also different regions of a common electron control layer.

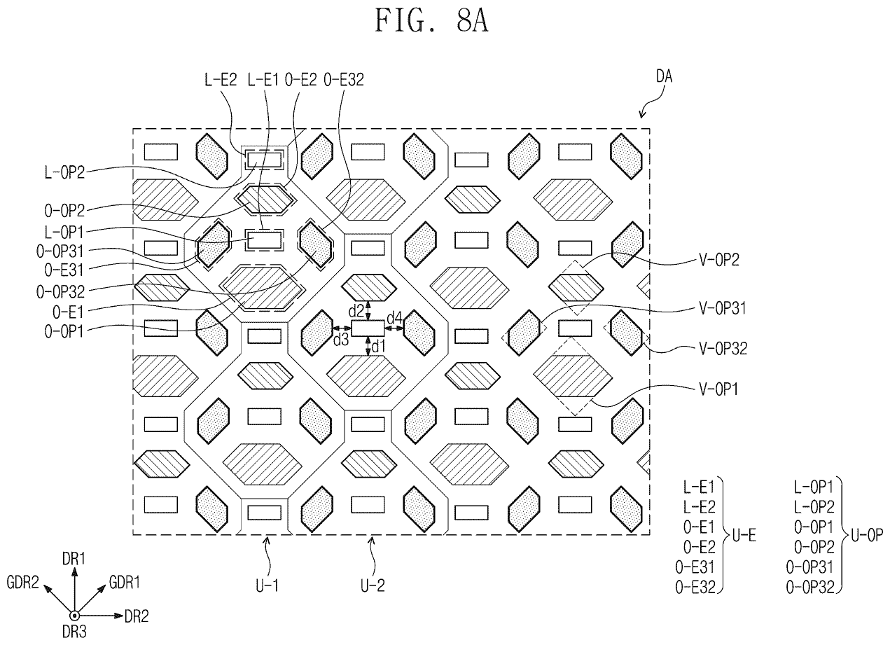

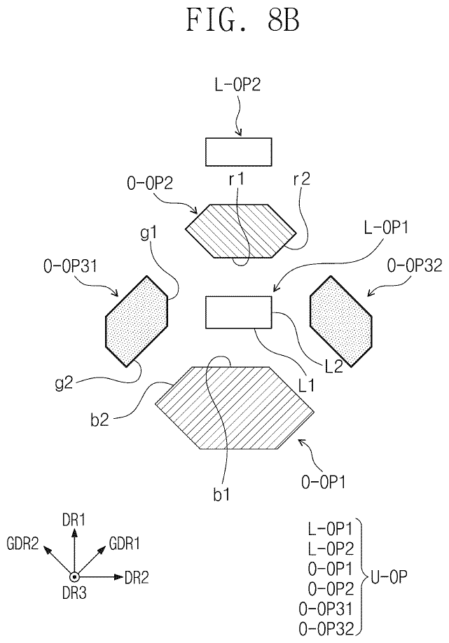

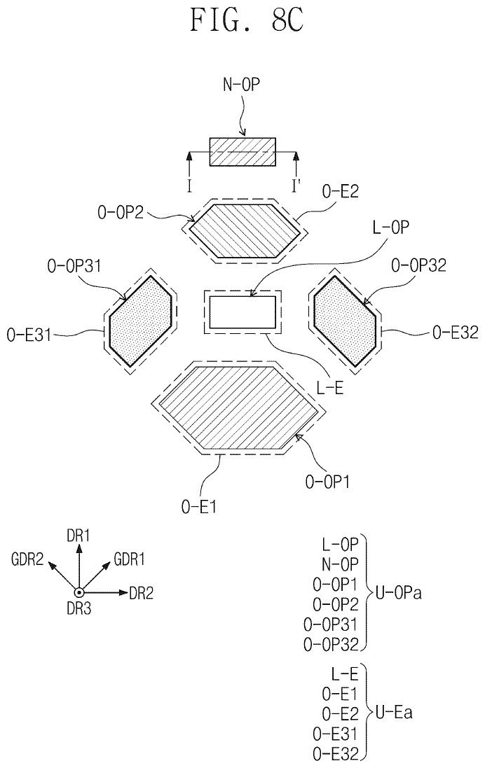

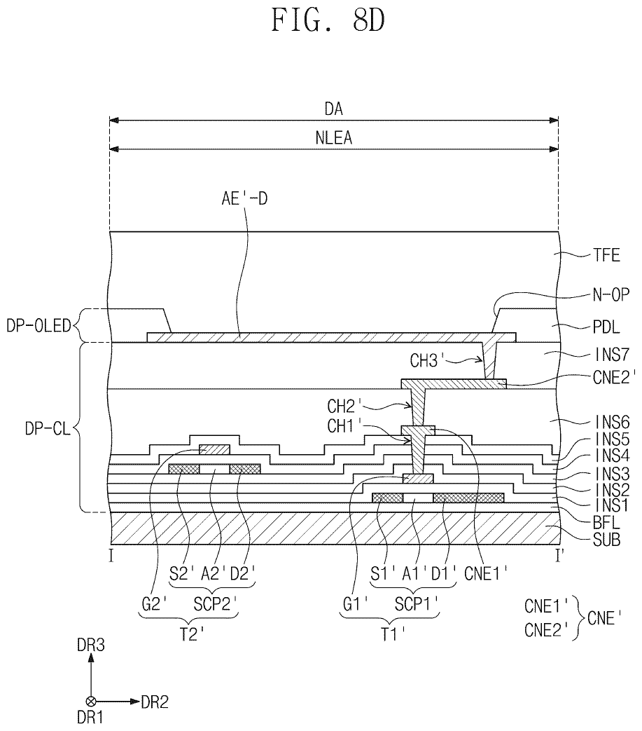

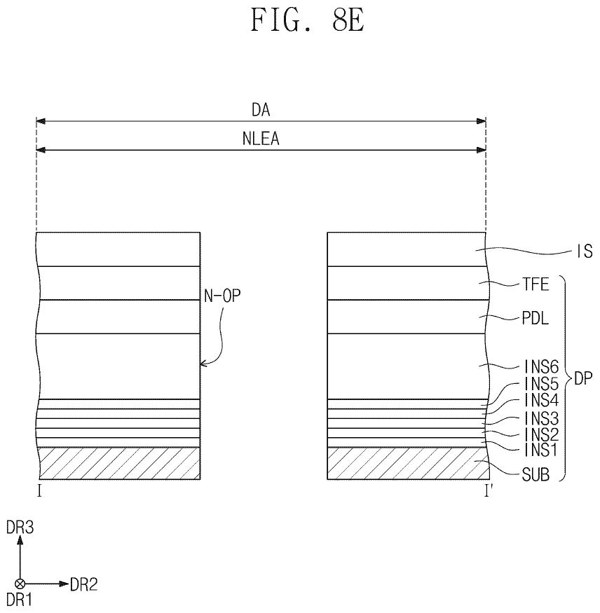

FIG. 8A is a diagram illustrating an arrangement state on a plane of light-emitting openings and sensing openings according to one or more embodiments of the present disclosure. FIG. 8B is an enlarged diagram of one unit region illustrated in FIG. 8A. FIG. 8C is an enlarged diagram of one unit region illustrated in FIG. 8A. FIG. 8D is a cross-sectional view taken along I-I′ of FIG. 8C. FIG. 8E is a cross-sectional view taken along I-I′ of FIG. 8C.

For convenience of description, the first electrodes AE (see FIG. 6) of configurations included in each of the light-emitting element OLED (see FIG. 6), and the first electrodes AE′ (see FIG. 6) of configurations include in each of the sensing element LRE (see FIG. 7), are illustrated as dotted lines. The first electrode AE displayed as the dotted lines may be referred as “a light-emitting element,” and the first electrode AE′ may be referred to as “a sensing element.”

Referring to FIG. 8A, a display device DD according to one or more embodiments may include unit elements U-E located in a display region DA. The unit elements U-E may be arranged having a constant rule in the display region DA. For example, a first column unit element U-1 and a second column unit element U-2 may each include the unit elements U-E arranged in the first direction DR1. The second column unit element U-2 may be shifted from the first column unit element U-1 along a first diagonal direction GDR1.

The unit elements U-E may each include a first light-emitting element O-E1, a second light-emitting element O-E2, a (3-1)-th light-emitting element O-E31, a (3-2)-th light-emitting element O-E32, a first optical sensing element L-E1, and a second optical sensing element L-E2.

The first light-emitting element O-E1 may supply first color light, the second light-emitting element O-E2 may supply second color light, and the (3-1)-th light-emitting element O-E31 and the (3-2)-th light-emitting element O-E32 may supply third color light. The first color light may have a blue color, the second color light may have a red color, and the third color light may have a green color. However, the present disclosure is not limited thereto, and the first to third color light may be changed to other color light.

A number of the first and second sensing elements L-E1 and L-E2 included in one unit element U-E may be the same as a number of the (3-1)-th light-emitting element O-E31 and the (3-2)-th light-emitting element O-E32 supplying the third color light. That is, when n light-emitting elements supplying the third color light are located in the one unit element U-E, n sensing elements may be also located in the one unit element U-E (e.g., n may equal 2).

Each of the first light-emitting element O-E1, the second light-emitting element O-E2, the (3-1)-th light-emitting element O-E31, and the (3-2)-th light-emitting element O-E32 may include the pixel driver PC described in FIG. 5, and may include the light-emitting element OLED described in FIG. 6. Each of the first optical sensing element L-E1 and the second optical sensing element L-E2 may include the sensor driver SNC described in FIG. 5 and may include the optical sensing element LRE described in FIG. 7.

The first light-emitting element O-E1 and the second light-emitting element O-E2 may be spaced apart from each other along the first direction DR1. The (3-1)-th light-emitting element O-E31 and the (3-2)-th light-emitting element O-E32 may be spaced apart from each other along the second direction DR2 with the first optical sensing element L-E1 therebetween. The (3-1)-th light-emitting element O-E31 may be spaced apart from the first light-emitting element O-E1 along the second diagonal direction GDR2, and the (3-2)-th light-emitting element O-E32 may be spaced apart from the first light-emitting element O-E1 along the first diagonal direction GDR1. The first optical sensing element L-E1 may be spaced apart from the second optical sensing element L-E2 along the first direction DR1 with the second light-emitting element O-E2 therebetween.

Unit openings U-OP may be defined in the pixel-defining layer PDL (see FIGS. 6 and 7). One unit opening U-OP may correspond to one unit element U-E. The unit openings U-OP may be arranged having a constant rule in the display region DA.

Each of the unit openings U-OP may include a first light-emitting opening O-OP1, a second light-emitting opening O-OP2, a (3-1)-th light-emitting opening O-OP31, a (3-2)-th light-emitting opening O-OP32, a first sensing opening L-OP1, and a second sensing opening L-OP2.

The first light-emitting opening O-OP1, the second light-emitting opening O-OP2, the (3-1)-th light-emitting opening O-OP31, and the (3-2)-th light-emitting opening O-OP32 may correspond to the light-emitting opening PDL-OP1 described in FIG. 6. The first sensing opening L-OP1 and the second sensing opening L-OP2 may correspond to the sensing opening PDL-OP2 described in FIG. 7.

The first light-emitting opening O-OP1 may overlap the first light-emitting element O-E1, the second light-emitting opening O-OP2 may overlap the second light-emitting element O-E2, the (3-1)-th light-emitting opening O-OP31 may overlap the (3-1)-th light-emitting element O-E31, and the (3-2)-th light-emitting opening O-OP32 may overlap the (3-2)-th light-emitting element O-E32. The first sensing opening L-OP1 may overlap the first optical sensing element L-E1, and the second sensing opening L-OP2 may overlap the second optical sensing element L-E2.

The first light-emitting opening O-OP1 and the second light-emitting opening O-OP2 may be spaced apart from each other along the first direction DR1. The (3-1)-th light-emitting opening O-OP31 and the (3-2)-th light-emitting opening O-OP32 may be spaced apart from each other along the second direction DR2 with the first sensing opening L-OP1 therebetween. The (3-1)-th light-emitting opening O-OP31 may be spaced apart from the first light-emitting opening O-OP1 along the second diagonal direction GDR2. The (3-2)-th light-emitting opening O-OP32 may be spaced apart from the first light-emitting opening O-OP1 along the first diagonal direction GDR1. The first sensing opening L-OP1 may be spaced apart from the second sensing opening L-OP2 along the first direction DR1 with the second light-emitting opening O-OP2 therebetween.

The first light-emitting opening O-OP1 may have a hexagonal shape in which a first portion facing the first sensing opening L-OP1 in the first direction DR1, and a second portion, which is point-symmetrical with the first portion, are removed. For example, the first light-emitting opening O-OP1 may have a hexagonal shape in which the first portion and the second portion of an imaginary rectangular shape V-OP1, which extends along the second diagonal direction GDR2, are removed.

The second light-emitting opening O-OP2 may have a hexagonal shape in which a first portion facing the first sensing opening L-OP1 in the first direction DR1, and a second portion point-symmetrical with the first portion and facing the second sensing opening L-OP2 in the first direction DR1, are removed. For example, the second light-emitting opening O-OP2 may have a hexagonal shape in which the first portion and the second portion of an imaginary rectangular shape V-OP2, which extends along the second diagonal direction GDR2, are removed.

The (3-1)-th light-emitting opening O-OP31 may have a hexagonal shape in which a first portion facing the first sensing opening L-OP1 in the second direction DR2, and a second portion point-symmetrical with the first portion, are removed. For example, the (3-1)-th light-emitting opening O-OP31 may have a hexagonal shape in which the first portion and the second portion of an imaginary rectangular shape V-OP31, which extends along the first diagonal direction GDR1, are removed.

The (3-2)-th light-emitting opening O-OP32 may have a hexagonal shape in which a first portion facing the first sensing opening L-OP1 in the second direction DR2, and a second portion point-symmetrical with the first portion, are removed. For example, the (3-2)-th light-emitting opening O-OP32 may have a hexagonal shape in which the first portion and the second portion of an imaginary rectangular shape V-OP32, which extends along the second diagonal direction GDR2, are removed.

The (3-1)-th light-emitting opening O-OP31 and the (3-2)-th light-emitting opening O-OP32 may be line-symmetrical with respect to an imaginary extension line extending along the first direction DR1, and crossing the center of the (3-1)-th light-emitting opening O-OP31 and the (3-2)-th light-emitting opening O-OP32. Accordingly, the (3-1)-th light-emitting opening O-OP31 and the (3-2)-th light-emitting opening O-OP32 may have the same area (e.g., same total area).

Each of the first sensing opening L-OP1 and the second sensing opening L-OP2 may have a rectangular shape including short sides extending along the first direction DR1, and including long sides extending along the second direction DR2 and having a greater length than the short sides. The first sensing opening L-OP1 and the second sensing opening L-OP2 may have the same area.

The first sensing opening L-OP1 and the second sensing opening L-OP2 included in each of the unit openings U-OP arranged along the first direction DR1 may be aligned along the first direction DR1.

Of the two unit opening U-OP located adjacent to each other along the second direction DR2 (or along the first diagonal direction GDR1 or along the second diagonal direction GDR2), the first sensing opening L-OP1 included in one unit opening U-OP, and the second sensing opening L-OP2 included in the other unit opening U-OP may be alternately arranged having a zigzag form along the second direction DR2. That is, the first sensing opening L-OP1 and the second sensing opening L-OP2 arranged along the second direction DR2, and located in the same row, may be alternately arranged having a zigzag form deviating in the first direction along the second direction DR2.

Referring to FIG. 8B, the first light-emitting opening O-OP1 may include a first side b1 facing the first sensing opening L-OP1 and extending along the second direction DR2, and a second side b2 facing the (3-1)-th light-emitting opening O-OP31 and extending along the first diagonal direction GDR1.

The second light-emitting opening O-OP2 may include a third side r1 facing the first sensing opening L-OP1 and extending along the second direction DR2, and a fourth side r2 facing the (3-2)-th light-emitting opening O-OP32 and extending along the first diagonal direction GDR1.

The (3-1)-th light-emitting opening O-OP31 may include a fifth side g1 facing the first sensing opening L-OP1 and extending along the first direction DR1, and a sixth side g2 facing the first light-emitting opening O-OP1 and extending along the first diagonal direction GDR1.

The first sensing opening L-OP1 may include a long side L1 extending along the second direction DR2, and a short side L2 extending along the first direction DR1 and having a smaller length than the long side L1.

According to one or more embodiments, the first side b1 has a greater length than the fifth side g1. The sixth side g2 has a greater length than the fifth side g1. In addition, a ratio of the second side b2 to the first side b1 may be greater than a ratio of the fourth side r2 to the third side r1.

Referring to FIG. 8A again, a distance from one long side of the first sensing opening L-OP1 to the first light-emitting opening O-OP1 may be a first width d1, a distance from the other short side of the first sensing opening L-OP1 to the second light-emitting opening O-OP2 may be a second width d2, a distance from one short side of the first sensing opening L-OP1 to the (3-1)-th light-emitting opening O-OP31 may be a third width d3, and a distance from the other short side of the first sensing opening L-OP1 to the (3-2)-th light-emitting opening O-OP32 may be a fourth width d4. The first to fourth widths d1, d2, d3, and d4 may be the same.

In addition, widths between light-emitting elements surrounding long sides and short sides of the second sensing opening L-OP2 may be also the same.

Light-emitting elements for supplying third color light in one unit element U-E and optical sensing elements may occur in the same number, thereby increasing resolution of the optical sensing elements LRE (see FIG. 7). In addition, distances from a sensing opening to light-emitting openings surrounding the sensing opening may be the same, thereby stably securing opening ratios of the light-emitting openings. Accordingly, a display device DD with increased light-emitting efficiency may be provided.

Referring to FIG. 8C, one unit element U-Ea according to an embodiment may include the first light-emitting element O-E1, the second light-emitting element O-E2, the (3-1)-th light-emitting element O-E31, the (3-2)-th light-emitting element O-E32, and the optical sensing element L-E1. Description for the first to (3-2)-th light-emitting elements O-E1, O-E2, O-E31, and O-E32 and the optical sensing element L-E1 may correspond to the light-emitting element and the optical sensing element described in FIGS. 5 to 7. The unit element U-Ea may be provided in plurality, and may be disposed in the display region DA with a constant rule such as what is described in FIG. 8A.

One unit opening U-OPa may correspond to the one unit element U-Ea. The one unit opening U-OPa according to an embodiment may include the first light-emitting opening O-OP1, the second light-emitting opening O-OP2, the (3-1)-th light-emitting opening O-OP31, the (3-2)-th light-emitting opening O-OP32, the sensing opening L-OP, and a penetration opening N-OP.

The first light-emitting opening O-OP1, the second light-emitting opening O-OP2, the (3-1)-th light-emitting opening O-OP31, the (3-2)-th light-emitting opening O-OP32 may correspond to the light-emitting opening PDL-OP1 described in FIG. 6. The sensing opening L-OP and the penetration opening N-OP may correspond to the sensing opening PDL-OP2 described in FIG. 7.

The first light-emitting opening O-OP1 may overlap the first light-emitting element O-E1, the second light-emitting opening O-OP2 may overlap the second light-emitting element O-E2, the (3-1)-th light-emitting opening O-OP31 may overlap the (3-1)-th light-emitting element O-E31, and the (3-2)-th light-emitting opening O-OP32 may overlap the (3-2)-th light-emitting element O-E32. The sensing opening L-OP may overlap the optical sensing element L-E.

According to the present embodiment, at least any one among configurations of the optical sensing element LRE described in FIG. 7 may be omitted in a region overlapping the penetration opening N-OP.

A cross-sectional view of a region corresponding to the penetration opening N-OP of FIG. 8C is exemplarily illustrated in FIG. 8D.

Referring to FIG. 8D, unlike a region overlapping the sensing opening L-OP, the region overlapping the penetration opening N-OP may have a structure in which configurations, disposed on the anode AE′, among configurations of the optical sensing element LRE described in FIG. 7 are omitted.

FIG. 8D exemplarily illustrates a dummy electrode AE′-D formed in the same process as the anode AE′, but the dummy electrode AE′-D may be defined in a floated state. A pixel-defining film PDL may be disposed on the dummy electrode AE′-D. The penetration opening N-OP at least partially exposing the dummy electrode AE′-D may be defined in the pixel-defining film PDL.

According to the present embodiment, “an dummy sensing element” in which any one among configurations of the optical sensing element LRE (see FIG. 7) is omitted may be disposed in any one among openings disposed in the one unit opening U-OPa. The penetration opening N-OP overlapping the dummy element may not contribute to optical sensing.

However, an embodiment of the inventive concept is not limited thereto, and position of the sensing opening L-OP and the penetration opening N-OP among the configurations described in FIG. 8C may be changed. In addition, the penetration opening N-OP may be additionally disposed in the one unit opening U-OPa, and an embodiment of the inventive concept is not limited thereto.

In addition, other configurations among the configurations of the optical sensing element LRE (see FIG. 7) may be omitted, or all thereof may be omitted, and an embodiment of the inventive concept is not limited thereto.

Referring to FIG. 8E, the penetration opening N-OP according to an embodiment may be a hole defined by penetrating a display panel DP and an input sensor IS.

According to an embodiment, the penetration opening N-OP may be defined by penetrating a base layer SUB, an encapsulation layer TFE, and the input sensor IS formed on the encapsulation layer TFE in a continuous process.

According to an embodiment, the inside of the penetration opening N-OP may be filled with an organic material, or may be provided as an empty space, and an embodiment of the inventive concept is not limited thereto.

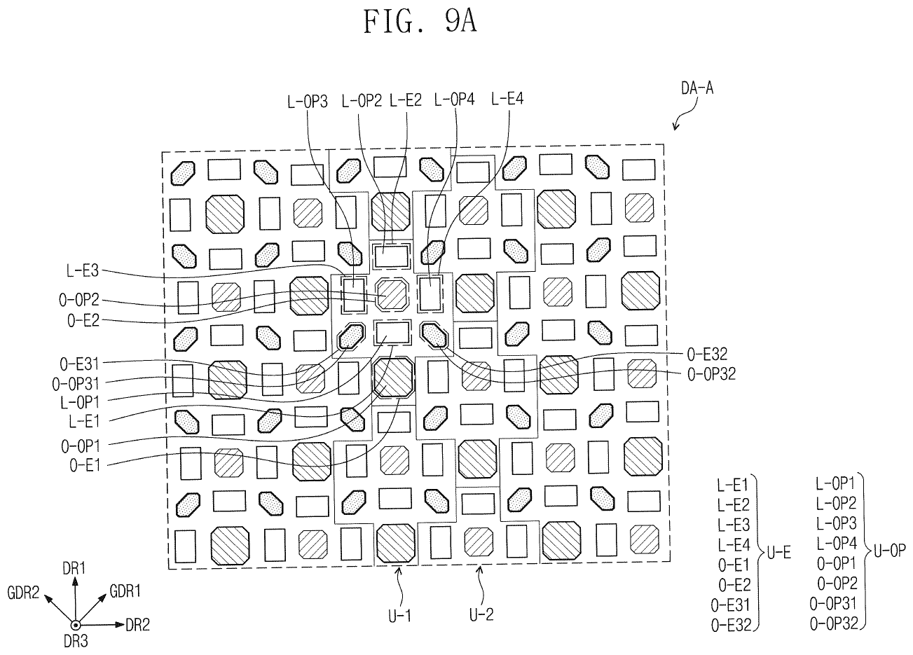

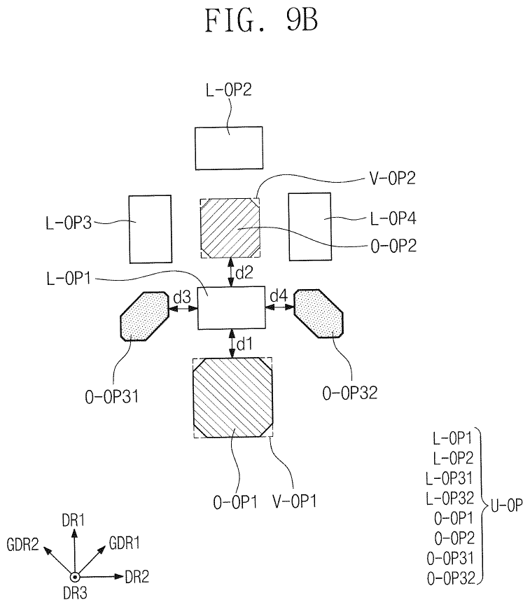

FIG. 9A is a diagram illustrating an arrangement state on a plane of light-emitting openings and sensing openings according to one or more embodiments of the present disclosure. FIG. 9B is an enlarged diagram of one unit region illustrated in FIG. 9A. For convenience of description, first electrodes AE (see FIG. 6) of configurations included in each of light-emitting elements OLED (see FIG. 6), and first electrodes AE′ (see FIG. 6) of configurations included in each of optical sensing elements LRE (see FIG. 7) are illustrated as dotted lines. The first electrode AE (see FIG. 6) displayed as the dotted line may be referred to as “a light-emitting element,” and the first electrode AE′ (see FIG. 6) may be referred to as “a sensing element.”

Referring to FIGS. 9A and 9B, a display device DD according to one or more embodiments may include unit elements U-E located in a display region DA-A. The unit elements U-E may be arranged having a constant rule in the display region DA-A. For example, each of a first column unit element U-1 and a second column unit element U-2 may include the unit elements U-E arranged in the first direction DR1. The second column unit element U-2 may be shifted from the first column unit element U-1 along the first diagonal direction GDR1.

The unit elements U-E may each include a first light-emitting element O-E1, a second light-emitting element O-E2, a (3-1)-th light-emitting element O-E31, a (3-2)-th light-emitting element O-E32, a first optical sensing element L-E1, a second optical sensing element L-E2, a third optical sensing element L-E3, and a fourth optical sensing element L-E4.

The first light-emitting element O-E1 may supply first color light, the second light-emitting element O-E2 may supply second color light, and the (3-1)-th light-emitting element O-E31 and the (3-2)-th light-emitting element O-E32 may supply third color light. The first color light may have a blue color, the second color light may have a red color, and the third color light may have a green color. However, the present disclosure is not limited thereto, and the first to third color light may be changed to other color light.

A number of the first to fourth optical sensing elements L-E1, L-E2, L-E3, and L-E4 included in one unit element U-E may be greater than a number of the (3-1)-th light-emitting element O-E31 and the (3-2)-th light-emitting element O-E32 supplying the third color light.

The first light-emitting element O-E1, the second light-emitting element O-E2, the (3-1)-th light-emitting element O-E31, and the (3-2)-th light-emitting element O-E32 may each include a pixel driver PC described in FIG. 5, and a light-emitting element OLED described in FIG. 6. The first to fourth optical sensing elements L-E1, L-E2, L-E3, and L-E4 may each include a sensor driver SNC described in FIG. 5 and an optical sensing element LRE described in FIG. 7.

The first light-emitting element O-E1 and the second light-emitting element O-E2 may be spaced apart from each other along the first direction DR1. The (3-1)-th light-emitting element O-E31 and the (3-2)-th light-emitting element O-E32 may be spaced apart from each other along the second direction DR2 with the first optical sensing element L-E1 therebetween. The (3-1)-th light-emitting element O-E31 may be spaced apart from the first light-emitting element O-E1 along the second diagonal direction GDR2, and the (3-2)-th light-emitting element O-E32 may be spaced apart from the first light-emitting element O-E1 along the first diagonal direction GDR1.

The first optical sensing element L-E1 may be spaced apart from the second optical sensing element L-E2 along the first direction DR1 with the second light-emitting element O-E2 therebetween. The third optical sensing element L-E3 may be spaced apart from the fourth optical sensing element L-E4 along the second direction DR2 with the second light-emitting element O-E2 therebetween. The third optical sensing element L-E3 may be aligned with the (3-1)-th light-emitting element O-E31 along the first direction DR1, and the fourth optical sensing element L-E4 may be aligned with the (3-2)-th light-emitting element O-E32 along the first direction DR1. The first to fourth optical sensing elements L-E1, L-E2, L-E3, and L-E4 may surround second light-emitting element O-E2.

Unit openings U-OP may be defined in the pixel-defining layer PDL (see FIGS. 6 and 7). One unit opening U-OP may correspond to one unit element U-E. The unit openings U-OP may be arranged having a constant rule in the display region DA.

The unit openings U-OP may each include a first light-emitting opening O-OP1, a second light-emitting opening O-OP2, a (3-1)-th light-emitting opening O-OP31, a (3-2)-th light-emitting opening O-OP32, a first sensing opening L-OP1, a second sensing opening L-OP2, a third sensing opening L-OP3, and a fourth sensing opening L-OP4.

The first light-emitting opening O-OP1 may overlap the first light-emitting element O-E1, the second light-emitting opening O-OP2 may overlap the second light-emitting element O-E2, the (3-1)-th light-emitting opening O-OP31 may overlap the (3-1)-th light-emitting element O-E31, and the (3-2)-th light-emitting opening O-OP32 may overlap the (3-2)-th light-emitting element O-E32.

The first sensing opening L-OP1 may overlap the first optical sensing element L-E1, the second sensing opening L-OP2 may overlap the second optical sensing element L-E2, the third sensing opening L-OP3 may overlap the third optical sensing element L-E3, and the fourth sensing opening L-OP4 may overlap the fourth optical sensing element L-E4.

The first light-emitting opening O-OP1 and the second light-emitting opening O-OP2 may be spaced apart from each other along the first direction DR1. The (3-1)-th light-emitting opening O-OP31 and the (3-2)-th light-emitting opening O-OP32 may be spaced apart from each other along the second direction DR2 with the first sensing opening L-OP1 therebetween. The (3-1)-th light-emitting opening O-OP31 may be spaced apart from the first light-emitting opening O-OP1 along the second diagonal direction GDR2, and the (3-2)-th light-emitting opening O-OP32 may be spaced apart from the first light-emitting opening O-OP1 along the first diagonal direction GDR1.

The first sensing opening L-OP1 may be spaced apart from the second sensing opening L-OP2 along the first direction DR1 with the second light-emitting opening O-OP2 therebetween. The third sensing opening L-OP3 may be spaced apart from the fourth sensing opening L-OP4 along the second direction DR2 with the second light-emitting opening O-OP2 therebetween. The first to fourth sensing openings L-OP1, L-OP2, L-OP3, and L-OP4 may surround the second light-emitting opening O-OP2.

The first light-emitting opening O-OP1 may have an octagonal shape. For example, the first light-emitting opening O-OP1 may have an octagonal shape in which corners of an imaginary square shape V-OP1 are removed.

The second light-emitting opening O-OP2 may have an octagonal shape. For example, the second light-emitting opening O-OP2 may have an octagonal shape in which corners of an imaginary square shape V-OP2 are removed.

The (3-1)-th light-emitting opening O-OP31 may have a shape of an octagon extending along the first diagonal direction GDR1. The (3-2)-th light-emitting opening O-OP32 may have a shape of an hexagon extending along the second diagonal direction GDR2.

The first sensing opening L-OP1 and the second sensing opening L-OP2 may each have a shape of a rectangle including short sides extending along the first direction DR1, and long sides extending along the second direction DR2 and having a greater length than the short sides. The first sensing opening L-OP1 and the second sensing opening L-OP2 may have the same area.

The third sensing opening L-OP3 and the fourth sensing opening L-OP4 may each have a shape of a rectangle including short sides extending along the second direction DR2, and long sides extending along the first direction DR1 and having a greater length than the short sides. The third sensing opening L-OP3 and the fourth sensing opening L-OP4 may have the same area.

The first sensing opening L-OP1 and the second sensing opening L-OP2 included in each of the unit openings U-OP arranged along the first direction DR1 may be aligned along the first direction DR1.

The third and fourth sensing openings L-OP3 and L-OP4 located adjacent to each other along the second direction DR2, and included in one unit opening U-OP may be arranged, along the second direction DR2, with the third and fourth sensing openings L-OP3 and L-OP4 included in another unit opening U-OP.

The first sensing opening L-OP1 included in one unit opening U-OP and the second sensing opening L-OP2 included in another unit opening U-OP, which are located adjacent to each other along the second direction DR2, may be alternately arranged having a zigzag form along the second direction DR2. That is, the first sensing opening L-OP1 and the second sensing opening L-OP2 arranged along the second direction DR2, and located in the same row may be alternately arranged having a zigzag form along the second direction DR2 (e.g., offset with respect to the first direction).

A distance from one long side of the first sensing opening L-OP1 to the first light-emitting opening O-OP1 may be a first width d1, a distance from the other long side of the first sensing opening L-OP1 to the second light-emitting opening O-OP2 may be a second width d2, a distance from one short side of the first sensing opening L-OP1 to the (3-1)-th light-emitting opening O-OP31 may be a third width d3, and a distance from the other short side of the first sensing opening L-OP1 to the (3-2)-th light-emitting opening O-OP32 may be a fourth width d4. The first to fourth widths d1, d2, d3, and d4 may be the same.

In addition, widths between the first to fourth sensing openings L-OP1, L-OP2, L-OP3, and L-OP4 surrounding long side and short sides of the second light-emitting opening O-OP2 may be the same.

Optical sensing elements present in one unit element U-E may be in greater number than light-emitting elements supplying the third color light in the one unit element U-E, thereby increasing resolution of the optical sensing element LRE (see FIG. 7). In addition, distances from a sensing opening to light-emitting openings surrounding the sensing opening may be the same, thereby stably securing opening ratios of the light-emitting openings. Accordingly, a display device DD with increased light-emitting efficiency may be provided.

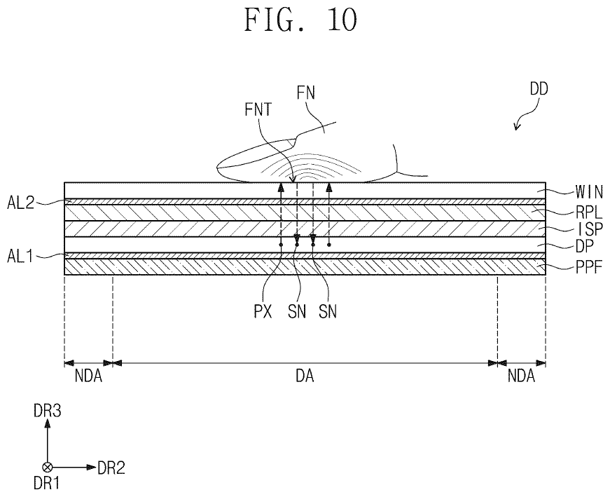

FIG. 10 illustrates a process of securing fingerprint information, which is biometric information, using optical sensors according to one or more embodiments of the present disclosure (e.g., using optical sensors SNij illustrated in FIGS. 5 and 7).

Referring to FIG. 10, a display device DD may include a plurality of optical sensors SN. The optical sensors SN may each have the same configuration as the optical sensors SNij illustrated in FIGS. 5 and 7. The optical sensors SN may detect a fingerprint FNT of a finger FN supplied to a display panel DP. Light generated by light-emitting elements OLED (see FIG. 6) of pixels PX may be supplied to, and reflected from, the fingerprint FNT. The fingerprint FNT is defined by a form of a valley and a ridge thereof, and reflectance of the valley is different from that of the ridge. The plurality of optical sensors SN receive light reflected on the valley or the ridge according to positions thereof. Information of the fingerprint FNT may be secured using the light received by plurality of optical sensors SN.

Light-emitting elements supplying a corresponding color light and optical sensing elements may be located in the same number in one unit pixel, thereby increasing resolution of the optical sensing elements.

In addition, distances from a sensing opening to light-emitting openings surrounding the sensing opening may be the same, thereby stably securing opening ratios of the light-emitting openings.

Accordingly, a display device with increased light-emitting efficiency may be provided.

In the above, description has been made with reference to preferred embodiments of the present disclosure, but those skilled in the art or those of ordinary skill in the relevant technical field may understand that various modifications and changes may be made to the disclosed embodiments within the scope and without departing from the present disclosure described in the claims. Therefore, the present disclosure is not limited to the contents described in the detailed description of the specification, but should be determined by the claims, with functional equivalents thereof to be included therein.

What is claimed is:

1. A display device comprising:
a base layer comprising a display region, and a non-display region around the display region in plan view;
unit elements at the display region, and comprising light-emitting elements and optical sensing elements; and
a pixel-defining layer defining unit openings comprising light-emitting openings for supplying light generated by the light-emitting elements, and sensing openings respectively overlapping the optical sensing elements,
wherein the light-emitting elements comprise
a first light-emitting element for supplying light of a first color,
a second light-emitting element for supplying light of a second color that is different from the first color, and spaced apart from the first light-emitting element along a first direction, and
a (3-1)-th light-emitting element and a (3-2)-th light-emitting element for supplying light of a third color that is different from the first color and from the second color, and spaced apart along a second direction crossing the first direction, and
a number of the optical sensing elements in one of the unit elements is equal to or greater than 2.

2. The display device of claim 1, wherein the optical sensing elements in the one of the unit elements comprise:
a first optical sensing element between the (3-1)-th light-emitting element and the (3-2)-th light-emitting element; and
a second optical sensing element spaced apart from the first optical sensing element along the first direction with the second light-emitting element therebetween,
wherein the light-emitting openings in one of the unit openings comprise:
a first light-emitting opening overlapping the first light-emitting element;
a second light-emitting opening overlapping the second light-emitting element;
a (3-1)-th light-emitting opening overlapping the (3-1)-th light-emitting element; and
a (3-2)-th light-emitting opening overlapping the (3-2)-th light-emitting element, and
wherein the sensing openings in the one of the unit openings comprise:
a first sensing opening overlapping the first optical sensing element; and
a second sensing opening overlapping the second optical sensing element.

3. The display device of claim 2, wherein first sensing openings and second sensing openings respectively in ones of the unit openings, which are arranged along the first direction, are aligned along the first direction.

4. The display device of claim 2, wherein first sensing openings and second sensing openings respectively in ones of the unit openings, which arranged along the second direction, are alternately arranged to have a zigzag form along the second direction.

5. The display device of claim 2, wherein the first sensing opening and the second sensing opening respectively have a shape of a rectangle comprising short sides extending in the first direction, and long sides extending in the second direction.

6. The display device of claim 5, wherein the first light-emitting opening and the second light-emitting opening have a hexagonal shape corresponding to an imaginary rectangle extending in a diagonal direction crossing the first direction and the second direction, and from which a first portion facing one of the long sides of the first sensing opening in the first direction, and a second portion that is point-symmetrical with the first portion, are removed.

7. The display device of claim 6, wherein the (3-1)-th light-emitting opening and the (3-2)-th light-emitting opening have a hexagonal shape corresponding to an imaginary rectangle from which a third portion facing short sides of the first sensing opening in the second direction, and a fourth portion that is point-symmetrical with the third portion, are removed.

8. The display device of claim 7, wherein a length of a side of the first light-emitting opening facing the first sensing opening in the first direction is greater than a length of a side of the (3-1)-th light-emitting opening facing the first sensing opening in the second direction.

9. The display device of claim 7, wherein the first light-emitting opening comprises a first side facing the first sensing opening in the first direction, and a second side facing the (3-1)-th light-emitting opening in a first diagonal direction crossing the first direction and the second direction,
wherein the second light-emitting opening comprises a third side facing the first sensing opening in the first direction, and a fourth side facing the (3-1)-th light-emitting opening in a second diagonal direction crossing the first diagonal direction, and
wherein a ratio of the second side to the first side is greater than a ratio of the fourth side to the third side.

10. The display device of claim 2, wherein a length of a first side of the (3-1)-th light-emitting opening facing the first light-emitting opening in a first diagonal direction, which crosses the first direction and the second direction, is greater than a length of a second side of the (3-1)-th light-emitting opening facing the second light-emitting opening in a second diagonal direction, which crosses the first diagonal direction.

11. The display device of claim 10, wherein the (3-1)-th light-emitting opening and the (3-2)-th light-emitting opening are line-symmetrical with respect to an imaginary line extending in the first direction.

12. The display device of claim 1, wherein the optical sensing elements in the one of the unit elements comprise:
a first optical sensing element between the (3-1)-th light-emitting element and the (3-2)-th light-emitting element;
a second optical sensing element spaced apart from the first optical sensing element along the first direction with the second light-emitting element therebetween;
a third optical sensing element spaced apart from the first light-emitting element in a first diagonal direction crossing the first direction and the second direction; and
a fourth optical sensing element spaced apart from the third optical sensing element along the second direction with the second light-emitting element therebetween, and spaced apart from the first optical sensing element in a second diagonal direction crossing the first diagonal direction,
wherein the light-emitting openings in the one of the unit openings comprise:
a first light-emitting opening overlapping the first light-emitting element;
a second light-emitting opening overlapping the second light-emitting element;
a (3-1)-th light-emitting opening overlapping the (3-1)-th light-emitting element; and
a (3-2)-th light-emitting opening overlapping the (3-2)-th light-emitting element, and
wherein the sensing openings in the one of the unit openings comprise:
a first sensing opening overlapping the first optical sensing element;
a second sensing opening overlapping the second optical sensing element;
a third sensing opening overlapping the third optical sensing element; and
a fourth sensing opening overlapping the fourth optical sensing element.

13. The display device of claim 12, wherein the first sensing openings and the second sensing openings respectively in the unit openings arranged along the first direction are aligned along the first direction.

14. The display device of claim 12, wherein the third sensing openings and the fourth sensing openings respectively in the unit openings arranged along the second direction are aligned along the second direction.

15. The display device of claim 12, wherein the first sensing openings and the second sensing openings have a shape of a rectangle comprising first sides extending in the first direction, and second sides extending in the second direction, and having a greater length than the first sides, and
wherein the third sensing openings and the fourth sensing openings have a shape of a rectangle comprising third sides extending in the first direction, and fourth sides extending in the second direction, and having a smaller length than the third sides.

16. The display device of claim 12, wherein the first light-emitting opening and the second light-emitting opening have an octagonal shape corresponding to an imaginary square from which corners are removed.

17. The display device of claim 12, wherein the (3-1)-th light-emitting opening has a hexagonal shape extending in a first diagonal direction crossing the first direction and the second direction, and
wherein the (3-2)-th light-emitting opening has a hexagonal shape extending in a second diagonal direction crossing the first diagonal direction.

18. The display device of claim 1, wherein the sensing openings comprise short sides extending in the first direction, and long sides extending in the second direction, and
wherein a distance from one of the long sides of one of the sensing openings to a facing one of the light-emitting openings along the first direction is substantially equal to a distance from one of the short sides of the one of sensing openings to a facing another of the light-emitting openings along the second direction.

19. The display device of claim 1, wherein the first color is blue, the second color is red, and the third color is green.

20. The display device of claim 1, wherein the light-emitting elements comprise a first electrode at least partially exposed by the light-emitting openings, a second electrode, and a light-emitting layer between the first electrode and the second electrode,
wherein the optical sensing elements comprise a first sensing electrode at least partially exposed by the sensing opening, a second sensing electrode, and a photoelectric conversion layer between the first sensing electrode and the second sensing electrode, and
wherein the second electrode and the second sensing electrode are a common layer having an integrated shape.

21. A display device comprising:
a base layer including a display region and a non-display region around the display region;
unit elements disposed on the display region, and each including light-emitting elements, and at least one sensing element and an dummy sensing element; and
a pixel-defining film in which unit openings each including light-emitting openings to which light generated by the light-emitting elements included in the unit element is supplied, and openings which respectively overlap the at least one sensing element and the dummy sensing element are defined,
wherein the light-emitting elements included in the one unit element include:
a first light-emitting element supplying light having a first color;
a second light-emitting element supplying light having a second color different from the first color, and spaced apart from the first light-emitting element along a first direction; and
a (3-1)-th light-emitting element and a (3-2)-th light-emitting element each supplying light having a third color different from the first color and the second color, and spaced apart from each other along a second direction crossing the first direction, and
a sum of numbers of the at least one sensing element and the dummy sensing element included in the one unit element is equal to or more than a number of the (3-1)-th light-emitting element and the (3-2)-th light-emitting element.

22. The display device of claim 21, wherein the light-emitting openings included in the one unit opening comprise:
a first light-emitting opening overlapping the first light-emitting element;
a second light-emitting opening overlapping the second light-emitting element;
a (3-1)-th light-emitting opening overlapping the (3-1)-th light-emitting element; and
a (3-2)-th light-emitting opening overlapping the (3-2)-th light-emitting element, and
the openings included in the one unit opening comprise:
a sensing opening overlapping the at least one optical sensing element; and
a penetration opening overlapping the dummy sensing element.

23. The display device of claim 22, wherein the at least one optical sensing comprise a first sensing electrode at least partially exposed by the sensing opening, a second sensing electrode, and a photoelectric conversion layer disposed between the first sensing electrode and the second sensing electrode, and
at least any one of the first sensing electrode, the second sensing electrode, or the photoelectric conversion layer is omitted in the dummy sensing element.

24. A display device comprising:
a display panel including unit elements which each include light-emitting elements and at least one sensing element, and a pixel-defining film in which light-emitting openings to which light generated by the light-emitting elements included in the unit element is supplied, a sensing opening which overlaps the at least one sensing element, and unit openings which each include a penetration opening spaced apart from the sensing opening with the any one light-emitting opening therebetween are defined; and
an input sensor directly disposed on the display panel,
wherein the penetration opening is defined by penetrating the display panel and the input sensor.

25. The display device of claim 24, wherein the light-emitting elements included in the one unit element comprise:
a first light-emitting element supplying light having a first color;
a second light-emitting element supplying light having a second color different from the first color, and spaced apart from the first light-emitting element along a first direction; and
a (3-1)-th light-emitting element and a (3-2)-th light-emitting element each supplying light having a third color different from the first color and the second color, and spaced apart from each other along a second direction crossing the first direction.
